(19) United States
(12) Patent Application Publication
(10) Pub. No.: US 2023/0387650 A1
(43) Pub. Date: Nov. 30, 2023

(54) LASER BEAM MODULE PACKAGE INCORPORATING STAMPED METAL FREEFORM REFLECTIVE OPTICS

(71) Applicant: Senko Advanced Components, Inc., Hudson, MA (US)

(72) Inventors: Yang CHEN, Thousand Oaks, CA (US); Robert Ryan VALLANCE, Newbury Park, CA (US); King-Fu HII, Newbury Park, CA (US)

(21) Appl. No.: 18/301,989

(22) Filed: Apr. 17, 2023

Related U.S. Application Data
(60) Provisional application No. 63/331,712, filed on Apr. 15, 2022.
(60) Provisional application No. 63/481,146, filed on Jan. 23, 2023.
(60) Provisional application No. 63/481,141, filed on Jan. 23, 2023.

(51) Int. Cl. H01S 5/02255; H01S 5/02253

(52) U.S. Cl. CPC H01S 5/02255; H01S 5/02253; H01S 5/4031

(57) ABSTRACT

An LBM package and method for packaging an LBM using a stamped metallic mirror array that folds light beams, correct beam shapes, fold and/or redirect beam propagations. The mirror array can be integrated or assembled inside an LBM to provide beam shaping and redirection of the high-power beams near the laser diode. The LBM incorporates a stamped metallic freeform mirror or reflector with an off-axis parabolic shape is configured to fold and collimate laser beam. A precision stamping process is deployed to produce an array of miniature, freeform mirrors in high volume applications. The mirror array simplifies the optical path and eliminates passive components such as refractive lenses and dichroic filters that combine RGB beams. Stamped metallic optical components with micro-scale freeform mirrors in the LBM are tolerant of high temperatures and can thermally diffuse heat away from the reflective surface for high power applications.

### PRIORITY CLAIM

This application claims the priorities of (a) U.S. Provisional Patent Application No. 63/331,712 filed on Apr. 15, 2022; (b) U.S. Provisional Patent Application No. 63/481,141 filed on Jan. 23, 2023; and (c) U.S. Provisional Patent Application No. 63/481,146 filed on Jan. 23, 2023. These applications are fully incorporated by reference as if fully set forth herein. All publications noted below are fully incorporated by reference as if fully set forth herein.

### BACKGROUND OF THE INVENTION

### Field of the Invention

The present invention relates to laser modules, and more particularly to a laser module package incorporating reflectors to reshape and redirect laser beams.

### Description of Related Art

FIG. 1A depicts the laser beam output of a typical edge emitting diode laser 2. In particular, the laser beam propagates to a beam spot having an elliptical cross-section instead of a circular cross-section, because of different divergent angles in the orthogonal (x-y) directions. For example, as depicted in FIG. 1B, the laser beam 6 emanating from the edge emitting diode laser 2 exhibits a slow-axis divergent angle and fast-axis divergent angle, which might typically be about 10 degrees and 25 degrees, respectively. Furthermore, the beam has an astigmatism in which the slow axis focus is behind the fast axis focus and separated by the astigmatism distance. For certain applications, it is desirable to reshape the laser beam 6 to obtain as near a perfectly-collimated beam (low angle of divergence and nearly equal in both the fast and slow-axis) with a nearly circular (or a square) cross-section, and it can be further advantageous for some applications if the beam has a uniform irradiance at the intended target position at which the laser beam is incident.

Diode lasers are packaged in laser beam modules (LBMs). LBMs are assembled with refractive lenses, either inside or outside of the LBM to reshape and improve the quality of the folded laser beam. In addition, for LBMs having an edge-emitting diode laser that is mounted horizontally with respect the output path of the LBM, a glass prism having a planar reflective surface is assembled into the LBM to fold the source laser beam by 90 degrees prior to reshaping with refractive lenses. As shown in FIG. 2, the prior art LBM 10 includes a housing frame 1, in which an edge emitting laser 2 is mounted on a pedestal 11 that is attached to a substrate 3 that also supports a glass prism 4 having a planar reflective surface 5. The diverging laser beam 6 propagates to the reflective surface 5, which is redirected by the reflective surface 5 to pass through a glass cover 7 of the housing 1. A plano-convex lens 8 is provided above the glass cover 7 to reduce the divergence angle of the beam 6 into a more collimated beam 9 as an output of the LBM package 10. The current LBM packages thus involve a complex assembly of separate components including prism and lenses with several adhesive joints requiring stringent alignment and assembly processes. Hence, additional considerations and challenges are required in order to meet performance, tolerance, reliability, and overall mass requirements for specific applications.

Augmented, virtual, and mixed reality (individually and collectively referred to as “XR”) displays require miniature light engines that can be worn near the eye. Generally, XR displays that are based on laser beam scanner (LBS) architectures use light from a hermetically-sealed LBM and scan the light with a micro-electromechanical system (MEMS) mirror into a combiner. Heretofore, LBMs for XR applications are hermetically-sealed packages that separately enclose red (λᵣ=640 nm), green (λ_{g}=520 nm), and blue (λ_{b}=450 nm) laser diodes (LDs). The LDs are generally edge-emitting with a fast-axis and a slow-axis that diverges with angles of about θ_{f}=22° and θₛ=8°, respectively. It is therefore necessary to reshape the beams so that all three beams are nearly collimated and combined into a coincident circular spot on a scanning MEMS mirror(s). Light reflected from the scanning mirror(s) generates a display image through a combiner. All three laser beams must be corrected to achieve a circular spot on the scanning mirror. Heretofore, this was achieved with optical assemblies of individual lasers sealed in respective hermetic packages, dichroic beam splitters, and refractive lenses for slow- and fast-axis correction lenses. Hence, for a light engine based on an LBS architecture, the RGB LBMs, each having the general structure of the LBM package 10 depicted in FIG. 2, fold laser beams 90 degrees with glass prisms inside the separate laser module packages (each of a different color) and then collimate the beams with three individual plano-convex lenses outside the three laser module packages. All six components are aligned individually and fixed with glue, which require stringent alignment and assembly processes.

Miniature light engines for XR are becoming increasingly common and production volumes are rising. This requires new solutions for producing optics that are suitable for these applications with reduced weight and size on the light engine package.

Furthermore, advances in high-power solid-state lasers and fiber lasers continue to enable crucial technologies for society, with an ever-increasing number of applications such as manufacturing processes, LIDAR, Telecom/Datacom, aerospace, and defense. The power levels depend on the particular requirements of the application but can range from fractions of a Watt up to more than 10 kW. High-power lasers have many applications in diverse fields such as optical communication, material processing (manufacturing), free-space optics, and 3D vision techniques such as LiDAR. These applications require optical components that alter or redirect laser beams to be tolerant to harsh environments, stable to thermal changes, and tolerant of high-power levels that might otherwise damage materials or surfaces. Furthermore, incoherent combination of multiple laser beams, such as those used in directed-energy weapons, can achieve even greater power levels.

However, since the beginning of laser technology, limits in the power-handling capability of optical components were always an obstacle to the advancement of laser systems and applications operating at high power levels and improved beam quality. High power lasers introduce substantial thermal loads that cause thermal aberrations. For example, earlier thermal analysis found that even a refractive optic made of fused silica and BK7 subject to laser power of 1.5 kW could cause a temperature rise of about 2.5 K due to energy absorption. A high-power laser can damage optical components by melting, ablation, cracking, etc. Some of the laser damage mechanisms are thermal degradation effects, defect-induced damage, and nonlinear effects leading to catastrophic failures of optical media. Laser-induced damage (LID) is most often limited by defects at surfaces or within thin film coatings. Thus, the limiting value of an optical component is frequently given by the damage threshold of its surface, which might be coated to influence the optical properties.

The surface quality of the reflector or mirror is critical to prevent component failure under high-power operation. Because of the high intensities that are incident on optical components in LBM used in high-power applications, the optical assemblies often require lenses and mirrors that are manufactured by expensive processes. To achieve form and surface quality requirements, heretofore, it is common to use expensive processes like single-point machining or grinding followed by polishing to achieve both form and finish requirements in either refractive or reflective materials. This is challenging for high-volume commercial products particularly when the applications also have stringent cost targets.

High power laser systems used in material processing, 3D imaging like LiDAR, and optical communication are becoming increasingly common and production volumes are rising. This requires new solutions for producing reflective optics that are suitable for these applications.

Accordingly, what is needed is an improved approach to packaging an LBM which can achieve lower costs for high-volume applications, and further improve tolerance, manufacturability, and reliability.

### SUMMARY OF THE INVENTION

The present invention overcomes the drawbacks of the prior art, providing new solutions for producing LBMs with reflective optics that are suitable for high-power as well as miniaturized applications. The present invention provides design flexibility to construct LBMs with improvements in size, weight, reliability, and cost.

In one aspect, the present invention provides an improved LBM package (e.g., a red, green, and blue (RGB) LBM) and method for packaging an LBM using a stamped metallic mirror array that folds light beams, correct beam shapes, and redirect beam propagations (e.g., to a MEMS mirror. The mirror array can be assembled inside a laser diode package to provide beam shaping and redirection of the high-power beams near the laser diode.

In one embodiment, the inventive LBM incorporates a stamped metallic freeform mirror or reflector (e.g., a stamped aluminum mirror) with an off-axis parabolic shape that is configured to fold and collimate laser beam (e.g., a high-power laser similar to those used in LiDAR systems). The metallic mirror is tolerant to high power due to its high damage threshold and thermoelastic properties. The metallic mirror performs far better than similar mirror made of polymer or glass because it does not have catastrophic transient temperature rises due to high-power pulsed lasers, and its thermal aberrations due to steady-state temperature rises are less. The stamped freeform mirrors can achieve lower costs for high-volume applications.

In one embodiment, an ultra-high precision stamping process is deployed to produce an array of miniature, freeform mirrors in high volume applications. The mirror array simplifies the optical path and eliminates passive components, for example, refractive lenses such as those used for slow-axis and fast-axis corrections, and dichroic filters that combine RGB beams. This new approach reduces the size, weight, and cost of LBMs for XR applications, as well as for high-power applications. Stamped metallic optical components with micro-scale freeform mirrors in the LBM are tolerant of high temperatures and can thermally diffuse heat away from the reflective surface for high power applications.

In one embodiment employing freeform reflective surfaces, a specific mirror array with aspherical shape is configured to fold and collimate beams from three RGB laser diodes within a laser module package. The stamped metallic mirrors shape the laser diode beams for better circularity and beam combination.

As defined in the claims, the present invention is directed to a laser beam module package, comprising: an array of lasers outputting incident laser beams having an elliptical cross-sectional beam profile due to astigmatism of the incident laser beams; a housing having a substrate supporting a frame having a top side, wherein the housing has a space bounded by the frame receiving the array of lasers and supporting the array of laser on the substrate within the space; an optically transparent cover hermetically sealed to the top side of the frame; and a mirror array comprising a mirror body of a metal material having a plurality of mirrors defined on a surface of the mirror body by metal stamping the surface of the mirror body to form an array of smooth freeform reflective surfaces of the array of mirrors, wherein the mirror body is supported by, and received within the space of, the housing, wherein the array of mirrors are optically aligned to the array of lasers, wherein the freeform reflective surfaces are configured to reflect and reshape the beam profile of the corresponding incident laser beams to produce corresponding output laser beams that are directed towards the cover to be output from the laser beam module package.

In one embodiment, the freeform reflective surfaces are configured to correct astigmatism of the laser beams to produce output laser beams that are closer to collimated beams.

In one embodiment, the mirror body comprises a monolithic block of metallic material, wherein the mirrors are defined by stamping a surface of the monolithic block to integrally and simultaneously form the plurality of mirrors, and wherein mirrors are defined on a surface of the mirror body facing corresponding lasers in the array of lasers. The mirror body is supported by the substrate and/or the frame.

In one embodiment, the monolithic block is a base that is structurally coupled to the frame with the base inserted through an opening in the frame, wherein the base is structurally coupled to the frame upon stamping to define the mirrors on the body. In one embodiment, the base surrounds the inside wall of the opening in the frame, defining an opening in the mirror body to receive the array of lasers.

In another embodiment, the mirror body comprises a mirror array block having a bottom surface for attachment to the substrate and an angled surface facing the array of lasers, wherein the mirror array block comprises the monolithic block and wherein the mirrors are defined by stamping the angled surface of the monolithic block to integrally and simultaneously form the plurality of mirrors prior to attaching the bottom surface of the mirror array block onto the substrate. In a further embodiment the mirror array block further comprises an outer frame covering the surfaces of the monolithic block except the angled surface, wherein the frame defines the bottom surface of the mirror array block for attachment onto the substrate.

In one embodiment, the mirrors are concave aspherical reflective surfaces of the mirror body.

In one embodiment, the housing is made of a first material and the mirror body is made of a second material; wherein the second material is different from the first material. In a further embodiment, the substrate and the frame are separate components made of different materials, and wherein the frame is hermetically sealed to the substrate.

In one embodiment, the mirror array comprises a first mirror array comprising a first set of freeform mirrors and a second mirror array comprising a second set of freeform mirrors corresponding to and facing the first set of mirrors, wherein incident laser beams are directed to the first set of mirrors, wherein the first set of mirrors collimates and reflects the incident laser beams to the second set of mirrors, wherein the second set of mirrors further collimates and direct the collimated output laser beams to the cover to be output from the laser beam module package. In a further embodiment, the first set of mirrors are freeform aspherical cylindrical mirrors, and the second set of mirrors are freeform aspherical cylindrical mirrors.

In one embodiment, the freeform reflective surfaces of the mirror array is configured such that the output laser beams converges to a spot at a target plane at a reference distance from the laser beam module package.

In another aspect, the present invention is directed to a method or process of assembling the laser beam module package to obtained the above structures, comprising stamping to form the freeform reflective surfaces in the mirror array.

### BRIEF DESCRIPTION OF THE DRAWINGS

For a fuller understanding of the nature and advantages of the invention, as well as the preferred mode of use, reference should be made to the following detailed description read in conjunction with the accompanying drawings. In the following drawings, like reference letters and/or numerals designate like or similar parts throughout the drawings.

FIGS. 1A and 1B illustrate a typical laser beam emanating from an edge-emitting laser diode.

FIG. 2 is a schematic configuration of a prior art LBM package.

FIG. 3 is a schematic configuration of an LBM package having an aspherical stamped metal reflective surface in accordance with one embodiment of the present invention.

FIGS. 4A to 4E illustrate an LBM package in accordance with one embodiment of the present invention, wherein FIG. 4A is an exploded view, FIG. 4B is a perspective view, FIG. 4C is a sectional perspective view (without cover plate), FIG. 4D is a top view, and FIG. 4E is a sectional view.

FIG. 5A schematically depicts an array of aspherical reflective surfaces; FIG. 5B schematically depicts optical simulation of turning and reshaping incident laser beams; FIG. 5C schematically depicts optical simulation of turning and reshaping incident laser beams at a target plane using a stamped mirror array; FIG. 5D schematically depicts optical simulation of turning and reshaping incident laser beams through an optical aperture; FIG. 5E schematically illustrates the beam profiles of the optical simulated collimated beams in FIG. 5D.

FIG. 6A schematically depicts optical simulation of combining RGB beams from a mirror array, wherein the RGB beams overlap at a target plane at a reference distance; FIG. 6B schematically illustrates the RGB beam paths from the RGB lasers to the target plane at the reference distance.

FIG. 7A schematically illustrates comparison of beam profiles of laser beams reflected from aspherical reflective surfaces and a faceted reflective surface; FIG. 7B schematically illustrates beam paths of laser beams reflected from corresponding freeform mirrors having faceted reflective surfaces to achieve targeted beam profile of combined beams at a target distance from the reflective surfaces.

FIGS. 8A to 8D illustrate an LBM package in accordance with another embodiment of the present invention, wherein FIG. 8A is a perspective view, FIG. 8B is a perspective view of the mirror array block in FIG. 8A, FIG. 8C is a sectional perspective view, FIG. 8D is a schematic illustrating heat transfer from the mirror array block to the substrate and environment; FIG. 8E is an alternate mirror array block in accordance with another embodiment of the present invention.

FIG. 9A is a schematic perspective layout of two complementary mirror arrays for turning and reshaping of a plurality of laser beams, in accordance with one embodiment of the present invention; FIG. 9B schematically depicts optical simulation of beam profiles at a target plane at a reference distance; FIG. 9C schematically depicts optical simulation of residual wavefronts for the collimated beams at the target plane at the reference distance.

FIG. 10A is a schematic perspective layout of two complementary mirror arrays for turning, reshaping and redirecting/combining a plurality of laser beams at a target plane at a reference distance, in accordance with one embodiment of the present invention; FIG. 10B schematically depicts beam overlap for the laser beams at the target plane at the reference distance.

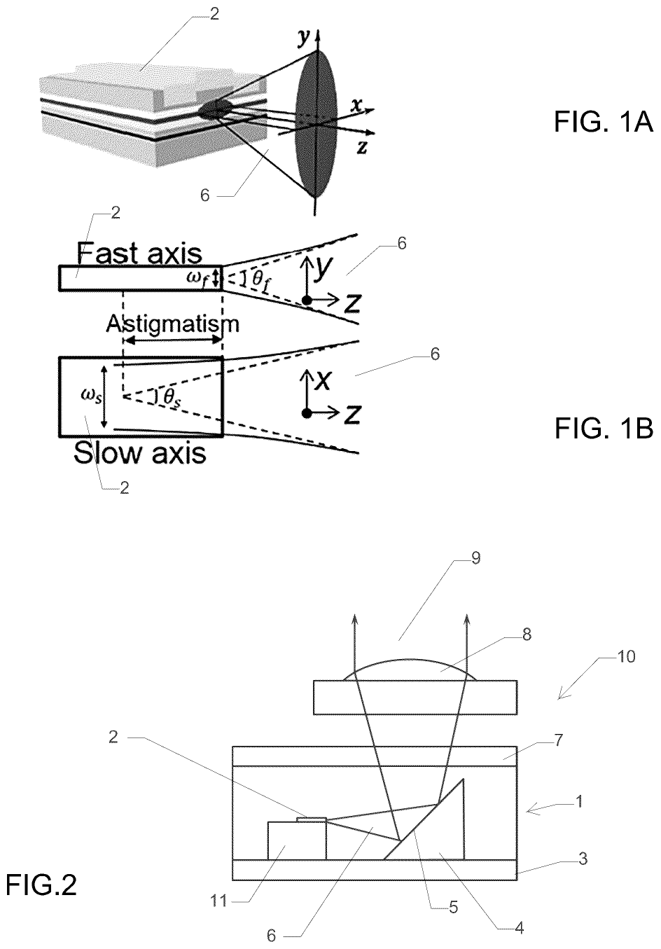

### DETAILED DESCRIPTION OF THE PREFERRED EMBODIMENTS

This invention is described below in reference to various embodiments with reference to the figures. While this invention is described in terms of the best mode for achieving this invention's objectives, it will be appreciated by those skilled in the art that variations may be accomplished in view of these teachings without deviating from the spirit or scope of the invention.

The present invention is described below using aspherical reflective surfaces as an example of freeform reflective surfaces. This does not preclude other types of freeform reflective surfaces from being adopted in accordance with the inventive concept.

In the illustrated embodiments, the present invention provides an improved approach for packaging a red, green, and blue (RGB) LBM using stamped mirror arrays that fold the light beam, correct beam shape, and redirect beam propagation (e.g., to a MEMS mirror). The mirror array simplifies the optical path and eliminates passive components like dichroic filters and refractive/diffractive lenses such as those used for slow-axis and fast-axis correction. This new approach reduces the size, weight, and cost of LBMs, e.g., for XR applications.

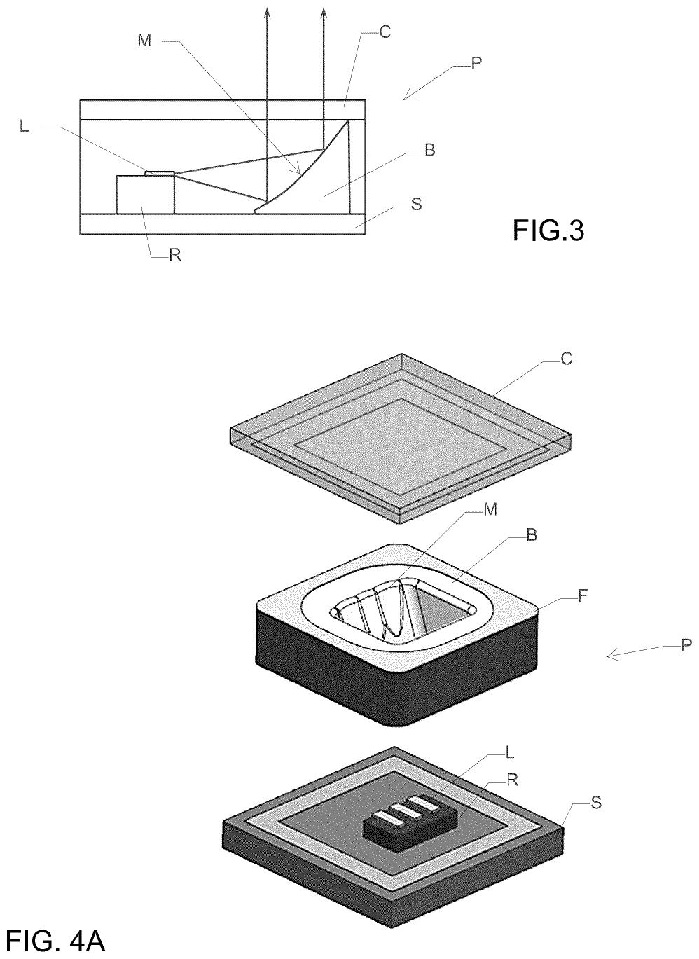

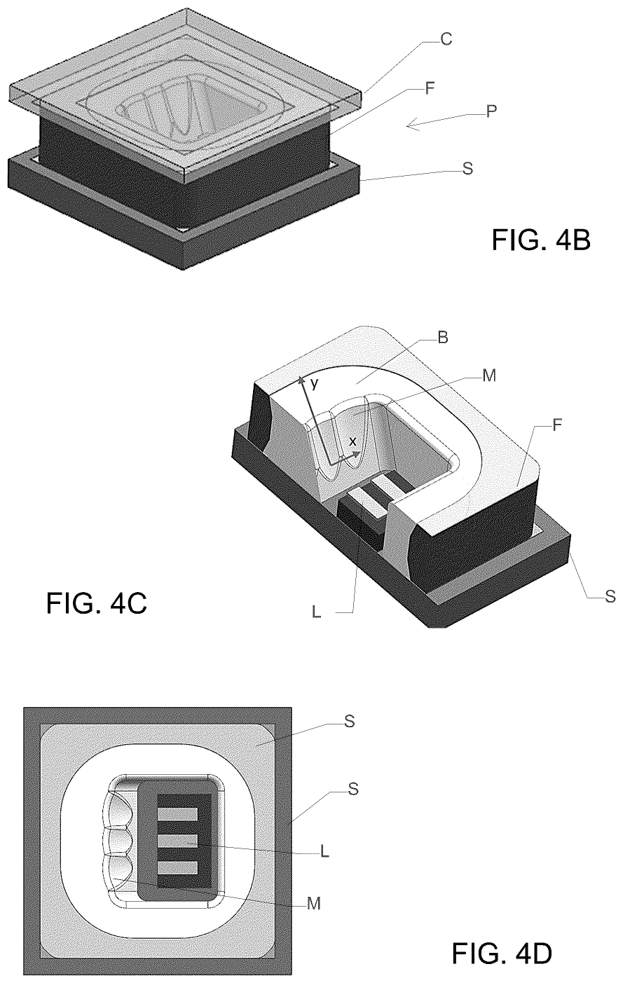

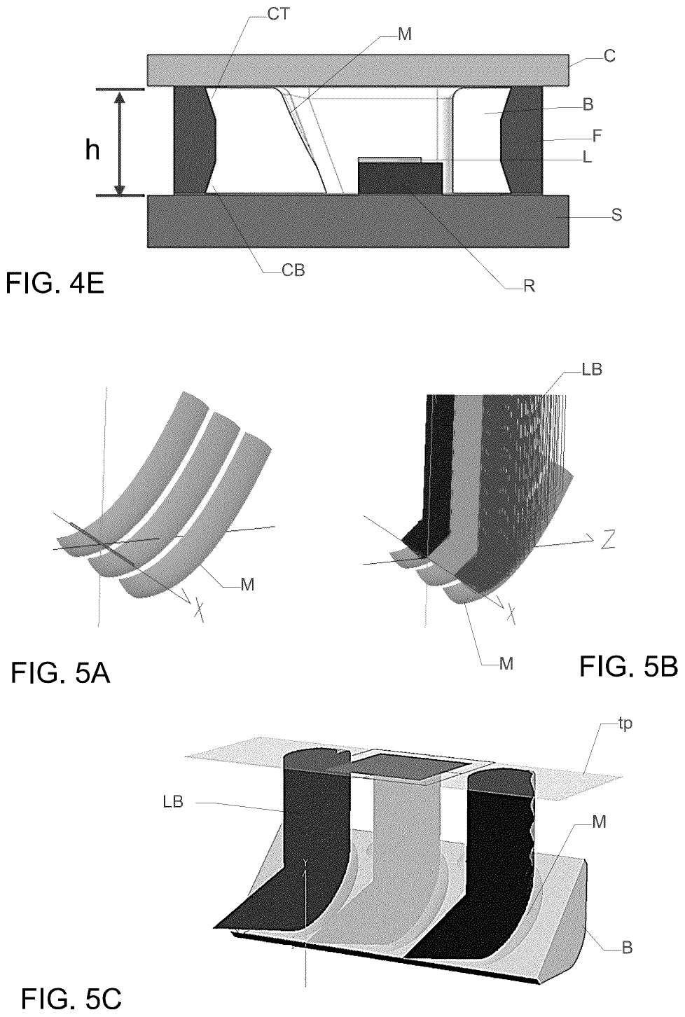

FIGS. 4A to 4E illustrate an LBM package P in accordance with one embodiment of the present invention, which may be represented schematically by FIG. 3. As shown in FIG. 3, the LBM package P comprises a hermetic housing that comprises a frame F supported on a substrate S, and a cover C supported on the frame F. The LBM package P further comprises an array of lasers L (e.g., edge-emitting diode lasers corresponding to R, G and B lights) supported on a riser R on the substrate S. The array of lasers L may be comprised in a diode laser chip. An array of non-planar, structured reflective surfaces or mirrors M, integrally and simultaneously defined by stamping a base B of metallic material, is optically aligned with the array of lasers L. In the illustrated embodiment, the base B is made out of a monolithic block of metal (e.g., Al), with the mirrors M integrally and simultaneously defined thereon by metal stamping processes. The base B may be supported by the frame F and/or the substrate S as shown in FIGS. 4C and 4E, with the array of lasers L/diode laser chip located within an opening in the base B. An optical transparent plate serves as the cover C (e.g., a glass cover). The LBM package P is hermetically sealed between the frame, the cover C and substrate S.

Each non-planar mirror M in the array serves both functions of reflecting and reshaping (e.g., collimating or focusing) a diverging incident light beam without relying on any refractive and/or diffractive optical element (i.e., without requiring a lens for reshaping the incident light beam). Each mirror M is an exposed free surface of the base B (i.e., surface exposed to air, or not internal within the body of the base B) having an exposed reflective free side facing an incident laser L, and wherein the exposed reflective free side comprises the structured reflective surface profile at which light is directed to and from the corresponding laser L. Each mirror M bends, reflects and/or reshapes an incident light beam from the laser L. Depending on the geometry and shape (e.g., curvature) of the structured reflective surface profile, the mirrors M may collimate, expand, or focus the incident light beam. For example, the structured reflective surface profile may comprise one of the following geometrical shape/profiles: (a) ellipsoidal, (b) off-axis parabolic, or (c) other freeform reflective optical surfaces. For example, the mirror surface, to provide optical power, may have a surface parametric function of any of the following, individually, or in superposition: ellipsoidal or hyperbolic conic foci, toroidal aspheric surfaces with various number of even or odd aspheric terms, X-Y aspheric surfaces with various number of even or odd terms, Zernike polynomials to various order, and various families of simpler surfaces encompassed by these functions. The surfaces may also be freeform surfaces with no symmetry along any plane or vector. For example, in the illustrated embodiment, the micro mirrors are generally freeform and concave.

The substrate S may be made of AlN (aluminum nitride), and its top surface is patterned with AuSn (gold/tin) plating for soldering to the bottom of the frame F. The cover C may be made of glass or quartz, and its bottom surface is patterned with AuSn plating for soldering to the top of the frame F. The frame F may be made of Kovar, with AuSn plating on top and bottom surfaces respectively facing the bottom surface of the cover C and top surface of the substrate S. The AuSn plating facilitates soldering of the cover C and the substrate S to the frame.

In the illustrated embodiment in FIG. 4, the hermetically sealed LBM package P includes a stamped metal base B that has three mirrors that simultaneously fold, redirect, and reshape each laser beam. In one embodiment, the base B is made of aluminum (Al), and the mirrors M are defined by integrally stamping the aluminum base B.

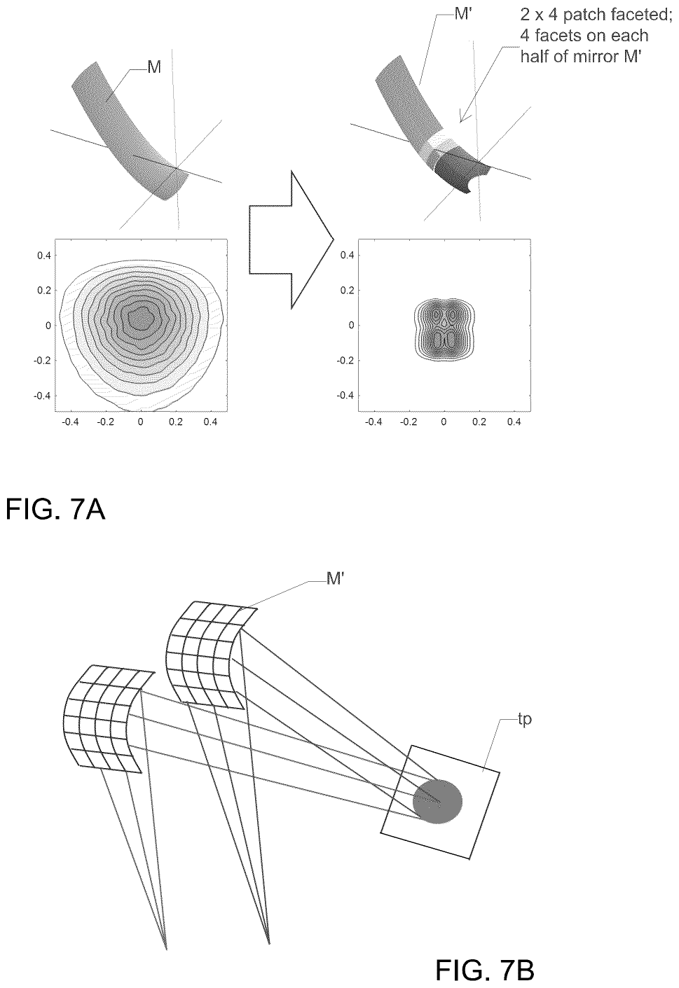

In accordance with the present invention, the mirrors M are manufactured with ultra-high precision stamping processes that produce miniature or micro-scale mirror surfaces with freeform shapes. In the stamping process, punches and dies squeeze a metallic workpiece until the metal yields and plastic deformation occurs, thereby imposing the shape of the punch and die into the workpiece. The stamped surface of each mirror is smooth, having a finish resembling a polished finish. (In an alternate embodiment, the structure reflective surface may have a compound profile defining more than one region corresponding to a different equivalent reflective surface (e.g., the faceted mirrors discussed in connection with FIGS. 7A and 7B)). These aluminum mirrors M, with form error better than 1 μm and surface roughness as low as Rₐ 4 nm, fold and reshape (focus, collimate, or expand) light beams. In one embodiment, the stamped mirrors M are made of high-purity aluminum (4N aluminum that is 99.99% pure). The aluminum has a low yield strength and is very ductile, which makes it suitable for stamping at room temperature. Furthermore, aluminum is highly reflective across the optical spectrum 12 ranging from 90 to 92% in the UV, dipping to about 86% around 0.8 μm and then rapidly increasing to about 94% at 1 μm, and continuing to increase to about 98% at around 10 μm. For visible light applications, the reflectivity can be improved with the deposition of a gold film or custom coating.

It is possible to achieve dimensional tolerances adequate for optical components with sub-micron tolerances on size, form, and location of features. This ultra-high precision stamping technology was used to manufacture metallic optical benches (MOBs) for optical communication and metallic optical reflectors (MORs) for LED illumination. This manufacturing technology can also be used to design and manufacture arrays of metallic freeform mirrors that can shape and redirect laser beams in laser beam modules. Micro mirrors expand the utility of MOBs by enabling light beams to be folded or even shaped using aspherical mirrors that focus or expand the light beams. This is accomplished without any additional cost of refractive or diffractive lenses, and the mirrors are aligned to the bench features by the stamping process.

U.S. Pat. No. 7,343,770 (the rights to which has have been acquired by Senko Advanced Components, Inc., the common assignee of the present invention) discloses a novel precision stamping system for manufacturing small tolerance parts. Such inventive stamping system can be implemented to produce the structures of the LBMs disclosed herein (including the structures for the base B having the mirrors M discussed above and similar stamped structures in the alternate embodiments discussed below). These stamping processes involve stamping a malleable bulk metal material (e.g., a metal blank or stock), to form the final surface features at tight (i.e., small) tolerances, including the reflective surfaces having a desired geometry in precise alignment with the other defined surface features. U.S. Pat. No. 9,782,814 (the rights to which has have been acquired by Senko Advanced Components, Inc., the common assignee of the present invention) further discloses a composite structure including a main portion and an auxiliary portion (an insert) of dissimilar metallic materials. The auxiliary portion is shaped by stamping. As the auxiliary portion is stamped, it interlocks with the main portion, and at the same time forming the desired structured features on the auxiliary portion, such as structured reflective surfaces. With this approach, relatively more critical structured features on the auxiliary portion are more precisely shaped with further considerations to define dimensions, geometries, locations relative to the main portion and/or finishes at relatively smaller tolerances. The disclosed composite structure may be adopted to produce the mirrors M within the frame F disclosed herein.

Referring to FIG. 4E, and the stamping process discussed in U.S. Pat. No. 9,782,814 (incorporated fully by reference herein), the base B is in the form of an Al insert is placed into a through opening in the frame F having annular chamfered top and bottom edges CT and CB. The insert is then shaped by stamping, including using a stamping punch that defines all the mirrors M in the array simultaneously. As the insert is stamped, it interlocks with the chamfered edges CT and CB of the frame F, forming a rivet structure corresponding to the base B, thereby structurally coupling to the frame F, and at the same time forming the array of mirrors M on the base B. The base B is thereby fixedly coupled to the frame like a rivet against the annular top and bottom chamfered edges CT and CB. In this configuration, the base B surrounds the inside wall of the through opening in the frame, defining an opening in the base to receive the array of lasers L. With this approach, the mirrors on the base B are precisely shaped simultaneously with respect to each other, and defining dimensions, geometries, locations relative to the frame F, spatial relationship of the mirrors within the array, and/or finishes at relatively smaller tolerances. The stamping process may involve several separate stamping operations, but the final stamping operation simultaneous completes the precise definition of the dimensions, geometries and finishes of all the mirrors M in the array and their positions relative to each other and the frame F. By accurately positioning the lasers L (or the laser diode chip) on the substrate S in reference to the frame F and within the central opening in the base B, the relative position of the lasers L and the mirrors M can be accurately defined, and hence the desired optical alignment of the lasers L and the mirrors M (i.e., the optical axis of the components) can be accurately achieved. This simplifies the overall assembly process to improve manufacturability, without compromising tolerance and reliability.

Referring to FIG. 4C, the micro mirrors M can have different radius of curvature and different focal spots for the X-Y axes (e.g., a double-axial hyperboloidal micro mirror), which correct the slow- and fast-axis variations for a particular target plane at a particular reference distance. The stamping process for the mirrors is designed using non-linear finite element analysis and computer simulation. Based on typical results from the simulation of the stamping process, the plastic strain is relatively uniform over most of the area inside the aperture, which suggests a fairly uniform grain structure on the surface of the mirror; the plastic strain distribution between the center of the aperture and the perimeter of the aperture and beyond the aperture can be predicted, so that the form error across the surface of the mirror array can also be predicted from the analysis. The form error was computed by calculating the deviations between the predicted 3D shape of the stamped mirror array and the ideal 3D CAD model. The predicted form error is corrected by adjusting the stamping tool. The simulations have been found to match experimental observations and can be relied upon as a trusted basis for compensation of stamping tool geometry. In the stamping process, punches and dies squeeze a metallic workpiece until the metal yields and plastic deformation occurs, thereby imposing the shape of the punch and die into the workpiece. Stamping tools can be produced which can form microscale features in the base B with location, size, and form tolerances better than one micrometer. The mirrors can be as small as a few hundred micrometers in size with sub-micron accuracy and surface finishes as low as Rₐ 4 nm without secondary processing.

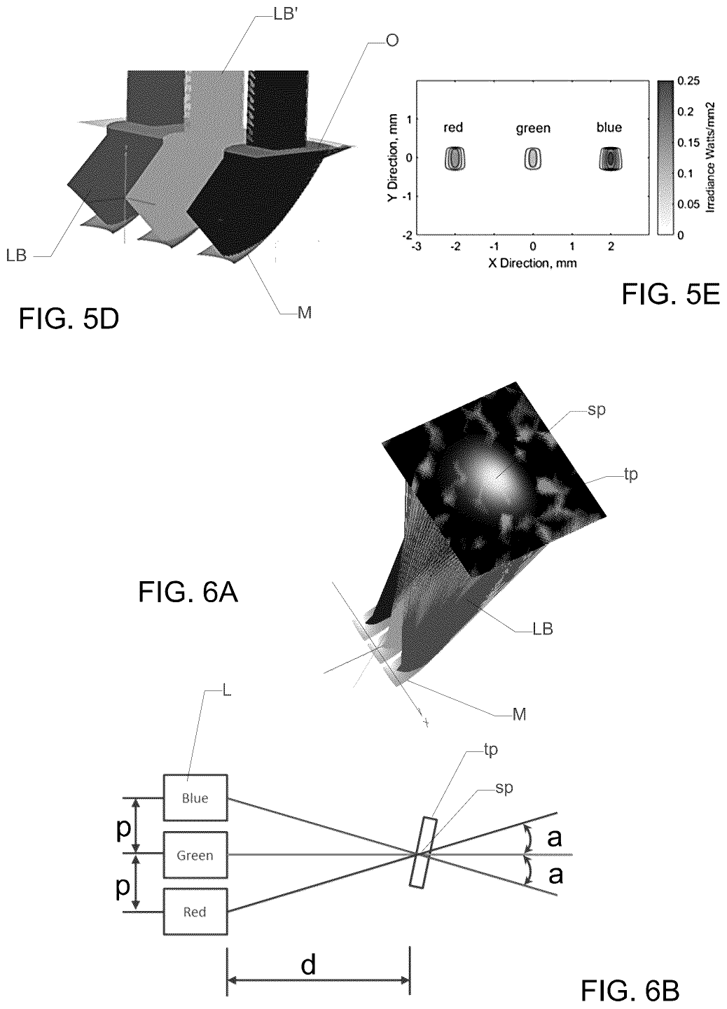

Furthermore, the freeform surface in the inventive stamped aluminum mirror array improves the quality of the beam beyond what can be achieved with refractive lenses that are spherical or plano-convex lenses. In the illustrated embodiment, an off-axis parabolic surface is used to achieve collimation of the divergent beams. FIG. 5A schematically depicts an array of freeform reflective surfaces which may be similar to the mirrors M discussed above; FIG. 5B schematically depicts optical simulation of the mirrors M turning and reshaping (collimating) incident laser beams into reshaped beams LB; FIG. 5C schematically depicts optical simulation of the mirrors M turning and reshaping (collimating) incident laser beams into the reshaped beams LB at a target plane tp at a reference distance d using a stamped mirror array (schematically depicted in FIG. 5C, which may be defined on the base B discussed in the embodiment above which is partially shown in FIG. 5C). Each mirror M can be optimized for the particular divergence properties (divergence angles and amount of astigmatism) for beam emitted from the laser diode array. The optical paths of three laser beams LB s reshaped by the mirror array are shown in FIG. 5C using rays that were simulated using commercially available software.

Due to the difference between the divergence angles of the laser's fast and slow axes, the output beam from a stamped mirror reflector will have a beam profile that is elongated to the target plane tp (see, the beam profile at the left hand side of FIG. 7A). To achieve a better circularity of the collimated beams, an optical aperture O can be used to trim the spot size along the fast axis direction. FIG. 5D schematically depicts optical simulation of the mirrors M turning and reshaping incident laser beams LB and passage of the reshaped beams LB through the optical aperture O. FIG. 5D shows the optical ray tracing simulation with the addition of the optical aperture O that masks a portion of the reshaped beams LB to achieve better circularity of the collimated beam LB′. FIG. 5E schematically illustrates the beam profiles of the optical simulated resultant collimated beams LB′ in FIG. 5D. As shown in FIG. 5E, the shape of beam profile is no longer elongated, and the width is about 0.62 mm 1/e² in both directions. However, nearly 50% of the output power is lost due to the optical mask, which adversely impacts power consumption leading to either less battery life or a larger battery.

The optical path for the LBM package P is illustrated in FIG. 3 with the stamped array of aspherical aluminum mirrors that simultaneously fold and collimate the light beams from the array of lasers L. The entire aluminum array of mirrors can be packaged inside the hermetic LBM package with a single attachment to the frame F (i.e., ‘riveting’ the base B with the mirrors defined thereon to the frame F, thus consolidate the functions of separate independent prisms and refractive lenses otherwise required in the prior art LBM packages (see FIG. 2).

As an example, in the illustrated embodiment in FIG. 4E, the height h of the frame F may be on the order of 1 mm. Miniature arrays of freeform mirrors may be produced for LBMs suited to XR applications. For these applications, the mirrors fold, route, and correct the light beams with a single optical component to reduce the size and weight of light engines. This new approach enables a reduction in the size, weight, reliability, and cost of LBMs and consequently light engines for XR applications by eliminating the need for collimating refractive lens assemblies; for some applications, it can also eliminate assemblies of dichroic filters that combine the RGB beams. Furthermore, the assembly process is simplified to a single optical alignment between the mirror array and the laser diodes which reduces manufacturing cost.

In a further aspect of the present invention, the mirrors M in the LBM package P may be configured to project reshaped laser beams LB from the array of lasers L (e.g., RGB lasers) to a spot sp on a target plane tp at a target or reference distance d from the lasers L. The geometries of the mirrors M in this embodiment will be different compared to the corresponding mirror M in FIG. 5, to effectively rotate (tilt) the mirrors M so that the reflected beams intersect at the target plane tp. The overlapping light beams LB at the target plane can achieve a desired color by moderating the RGB components targeted at the spot sp by moderating the relative intensities of the RGB laser beam outputs. FIG. 6A schematically depicts optical simulation of combining RGB beams from a mirror array, wherein the RGB beams overlap at a target plane tp at a reference distance d from the respective lasers L; FIG. 6B schematically illustrates the RGB beam paths from the RGB lasers, spaced at a pitch p, to the target plane tp at the reference distance d. The beams from the blue and the red lasers on each side of the green laser converge to the spot sp at the target plane tp at a target angle a. The target distance d may range from a few millimeters to few hundred millimeters.

In a further embodiment, a faceted freefrom mirror M′ can provide an effective way to achieve “flat top” beam shaping. FIG. 7A schematically illustrates the comparison of beam profiles of laser beams reflected from an aspherical reflective surface and a faceted reflective surface. In the illustrated example, on the left-hand side in FIG. 7A, the light source (e.g., a green diode laser) is targeted at target plane at a distance of 4 mm from the mirror M. On the right hand side in FIG. 7A, the same light source projects a light beam at the same target plane (i.e., 4 mm) at the same distance from the mirror M′. Unlike mirror M, the mirror M′ has a 2×4 patch faceted freeform reflective surface. The corresponding beam profile for the mirror M′ is shown to be a flat “flat top” beam in which the intensity of the light is more uniform over larger area, resulting in a less circular beam profile. FIG. 7B schematically illustrates beam paths of laser beams (two shown for simplicity) reflected from corresponding freeform mirrors M′ having faceted reflective surfaces to achieve a targeted beam profile of combined beams at a target distance from the mirrors M′. Each facet is defined by a NURBS (nonuniform rational B-spline) surface patch that collectively form the composite surface of mirror M′; each NURBS surface can be optimized to achieve targeted beam profile at the target distance.

The present invention further provides a more reliable platform for high-power LBMs. High-power optical assemblies are used in many applications with a range of power levels. For example, material processing such as laser cutting, welding, marking, drilling use lasers with powers in range of 500 W-750 W and are commercially available). In telecommunications, higher power helps achieve higher data rates over longer transmission distances. Pump lasers (980 nm) are used in erbium-doped fiber amplifiers that offer operating power levels from 100 mW to 1.6 W for telecommunications. Fiber-coupled diode lasers with powers of 10 W-200 W are used for laser pumping and material processing. Emerging autonomous vehicles require semiconductor lasers with hundreds of mW for light detection and ranging (LiDAR), while some other LiDAR applications (military, airborne topographic mapping, agriculture, space applications) may require even higher power levels (tens of kilowatts to tens of megawatts) using fiber lasers or solid-state lasers.

By adopting stamped mirrors made of high-purity aluminum (4N aluminum that is 99.99% pure), heat transfer is significantly improved to reduce damages from high-power lasers. Even in cases where the incident laser power does not approach the potential damage thresholds, aluminum mirrors still have substantial optical advantages. Aluminum is a superb conductor of heat; it easily dissipates any absorption of optical power away from the mirror surface. The heat can flow out of the mirror and into the substrate by thermal conduction or into the ambient environment by convection. This minimizes temperature rise in steady state and transient applications. Furthermore, aluminum's high thermal diffusivity prevents severe transient temperature spikes in pulsed high-power laser applications. These benefits are especially stark when compared to mirrors made of polymers commonly used for injection molding, e.g., a polyetherimide (PEI) that is commercially available. It has been found that aluminum's thermal diffusivity a is more than several hundred (e.g., on the order of 800) times greater than PEI. The coefficient of thermal expansion (CTE) of aluminum is only about 35-40% of that of PEI. The impact of these properties is taken into consideration in designing mirrors for LiDAR applications adopting the inventive concept.

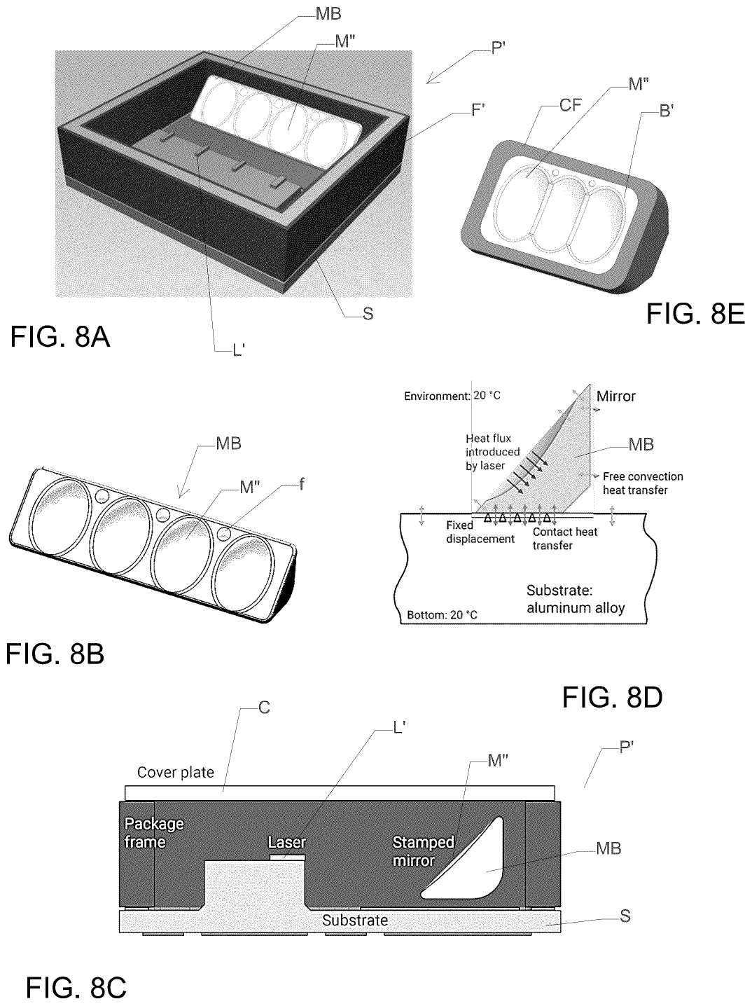

In accordance with another aspect of the present invention, a freeform mirror is developed to suit high-power applications, such as LiDAR applications. FIGS. 8A to 8D illustrate an LBM package in accordance with another embodiment of the present invention, wherein FIG. 8A is a perspective view, FIG. 8B is a perspective view of the mirror array block in FIG. 8A, FIG. 8C is a sectional perspective view, FIG. 8D is a schematic illustrating heat dissipation from the mirror array block to the substrate and environment; FIG. 8E is an alternate mirror array block in accordance with another embodiment of the present invention.

In the LBM package P′ shown in FIG. 8A, a mirror array block MB defining an array of freeform mirrors M″ is placed within the frame F′ and attached (e.g., by welding) to the substrate S that is hermetically sealed to the base of the frame F′. A plurality of lasers L′ (e.g., configured in a laser diode) is positioned on the substrate S. In this embodiment, there are shown four lasers L, corresponding four mirrors M″ on the mirror array block MB (see also FIG. 8B). Referring also to FIG. 8C, an optically transparent plate cover C is provided (as was in the earlier embodiment of LBM package P) to hermetically seal the package P″. FIG. 8C illustrates a cross-section through the laser L′ and freeform mirror M″. Fiducial features f may be provided on the mirror array block MB to facilitate identifying orientation of the mirror array block MB. The entire assembly shown is hermetically sealed, between the frame F′, cover C and substrate S.

The mirror array block MB is made of metal, e.g., 4N aluminum, as was in the case of the base B in the earlier embodiment. In the illustrated embodiment, the mirror array block MB is made out of a monolithic block of metal (e.g., Al), with the mirrors M″ integrally and simultaneously defined thereon by metal stamping processes. FIG. 8C illustrates a similar mirror that corrects and redirects a beam emitted within a high-power laser diode package. Similar mirror design considerations and stamping processes and procedures are applicable to this embodiment. Unlike the earlier embodiment, the array of mirrors M″ are simultaneously predefined on a separate block (MB) of aluminum to complete forming the mirror array block having the array of mirrors M″, prior to the mirror array block being attached onto the substrate S. The stamping processes and procedures may be adapted from the processes and procedures applied to the earlier embodiment. It is noted that the stamping process for this embodiment would define (e.g., simultaneously/integrally form) both the geometries and locations of the mirrors M″ along with the geometries and relative locations of the external surfaces of the mirror array block MB (having an overall generally triangular cylindrical structure). Accordingly, the bottom surface of the mirror array block MB is a reference surface to which optical axis of the mirrors M″ is defined relative to such bottom surface in the stamping process. After such bottom surface of the mirror array block MB is attached onto the substrate S, the optical axis of the mirrors M″ is known in relation to such bottom surface, thereby facilitating optical alignment of the mirrors M″ with the lasers L′ that are also attached onto the substrate S.

The present embodiment may also be applicable to XR applications. As an example, based on this embodiment, the dimensions of the stamped mirror can be about 2.1×5×0.9 mm with a volume of about 5.9 mm³; the mass is about 16 mg when made of high-purity aluminum with a density of 2.7 g/cm³. In the prior art LBMs, the volume of the prism is estimated to be about 1 mm³ with a mass of about 2.5 mg, and the volume and mass of each lens is about 1.26 mm 3 and 3.4 mg, respectively. Therefore, the total mass of a set of three prisms and three lenses in prior art LBM packages would be about 17.7 mg (without counting the fixture and epoxy for the lenses), as compared to the inventive aluminum mirror array block MB with a total mass of about 16 mg. In addition, reduced bill of material (BOM) and simplified packaging process further reduce the assembly complexity of entire light engine and improve reliability due to fewer adhesive joints.

Thermo-mechanical finite element analyses (FEA) are used to evaluate changes in the shape of the mirror due to changes in operating temperatures and incident flux. The optical performance is compared to a polymer mirror in both steady-state conditions such as a continuous wave laser beam and transient conditions such as pulsed laser used in LiDAR applications. The thermo-mechanical shape changes are subsequently used in optical simulations to evaluate thermal aberrations in the wavefront.

There are two thermo-mechanical mechanisms that might degrade the optical performance of a stamped mirror used in high power applications. The first mode is a transient thermal phenomena that can arise with pulsed lasers, and the second is a steady-state phenomena that can arise with continuous wave (CW) lasers. These phenomena are:
a. damage to the surface of the mirror due to short-pulse high-peak power that can cause localized but very high transient temperature increases, and
b. thermal aberration due to thermal expansion and changes in the form of the reflective surface when optical power is absorbed into the mirror and causes a temperature rise.

These two phenomena were analyzed for the optical design for two alternative materials. Comparing the results for a mirror stamped from high-purity 4N aluminum with a mirror made by injection molding using PEI polymers. In both cases, the mirror surface is assumed to be coated with to achieve a reflectivity of 99% at the operating wavelength. Finite element analyses (FEA) were conducted for both the transient pulse phenomena and the steady-state (static) phenomena. FIG. 8D is a schematic illustrating heat transfer from a mirror array block to the substrate and environment. As shown in FIG. 8D, the respective mirror array block (aluminum vs. polymer) was assumed to be mounted onto a thermally conductive substrate made of 2 mm thick aluminum alloy with thermally conductive contact between the mirror and substrate. All surfaces were set for free convection to ambient air at a temperature of 20° C. The incident laser beam was modeled as a heat flux equal to 1% of total laser power.

For the transient case of a pulsed laser, the laser is assumed to produce an optical power of 5 kW peak with a repetition rate of 1 kHz, a duty cycle of 0.05%, and a pulse width of 500 ns. This is representative of lasers used in LiDAR applications. A single cycle (pulse followed by cooling) is simulated as a 500 ns laser pulse followed by 0.9995 ms of cooling. The incident heat flux from the laser was set at 50 W (1% absorption of the 5 kW laser power) of incident flux onto the mirror surface during the pulse. Comparing the response for the aluminum and polymer mirrors, the aluminum mirror shows a much lower peak temperature of 65° C. compared to the polymer's peak temperature which reaches 237° C. during the single pulse exposure. Under this condition, the center of a polymer mirror reaches a temperature greater than its glass transition temperature of 210° C., which would certainly lead to permanent damage and aberrations. By contrast, the peak temperature of 65° C. on the aluminum mirror surface is still well within its safe range operating range limited by damage thresholds such as the melting temperature of 660° C. In addition, because of much higher thermal diffusivity, the aluminum mirror returns to the ambient temperature of 20° C. at the end of cycle. On the other hand, the polymer mirror cools much slower and still has a temperature near 39° C. at the start of the next pulse.

For the steady-state case which causes thermal aberrations as thermal expansion occurs during a temperature rise, a constant heat flux of 0.01 Watts is assumed to represent a 1 Watt CW beam incident on the mirrors 99% reflective coating. The steady-state temperature distribution within the mirror is observed for the polymer and aluminum mirrors. For the time to reach the equilibrium temperature for both mirrors, the polymer mirror reaches a much higher temperature in the aperture area, and it has a greater temperature gradient across of the face of the mirror. These temperature distributions induce thermo-elastic deformations due to the CTE of the materials.

The shapes of the mirrors at equilibrium were exported from the FEA software as 3D meshed bodies and then imported into the optical ray tracing software. Beam propagation was used to calculate the optical consequences as distortion of the wavefront. To validate the technique, the wavefront for the original mirror is checked using meshed geometry. The results for the faceted mesh of the original mirror (no thermal aberration) was negligible at only about 0.02 waves of distortion from a perfect flat wavefront across entire beam. The wavefront distortion is due to thermal aberration of the stamped aluminum mirror. The thermal aberration and change in the beam propagation direction was substantially worse for the polymer mirror. The wavefront before adjusting for error in beam propagation direction is about double that of the aluminum. The wavefront of the polymer mirror with a distortion in the collimated beam is about five times that of the aluminum mirror.

FIG. 8E is an alternate mirror array block MB′ in accordance with another embodiment of the present invention. In this embodiment, the mirror array block MB′ has a composite structure. The array of freeform mirrors M″ are integrally and simultaneously defined by metal stamping processes, on a monolithic metal (e.g., 4N Al) block B′ within a low CTE metal frame CF of a different material to improve on thermal expansion effect. The frame CF may be made of Kovar/Invar. The outer frame CF covers the surfaces of the monolithic block except the angled surface defined with the mirrors M″. The mirrors M″ are formed with similar design considerations as the previous embodiments. The frame CF is attached onto the substrate S in place of the mirror array block MB in FIG. 8B.

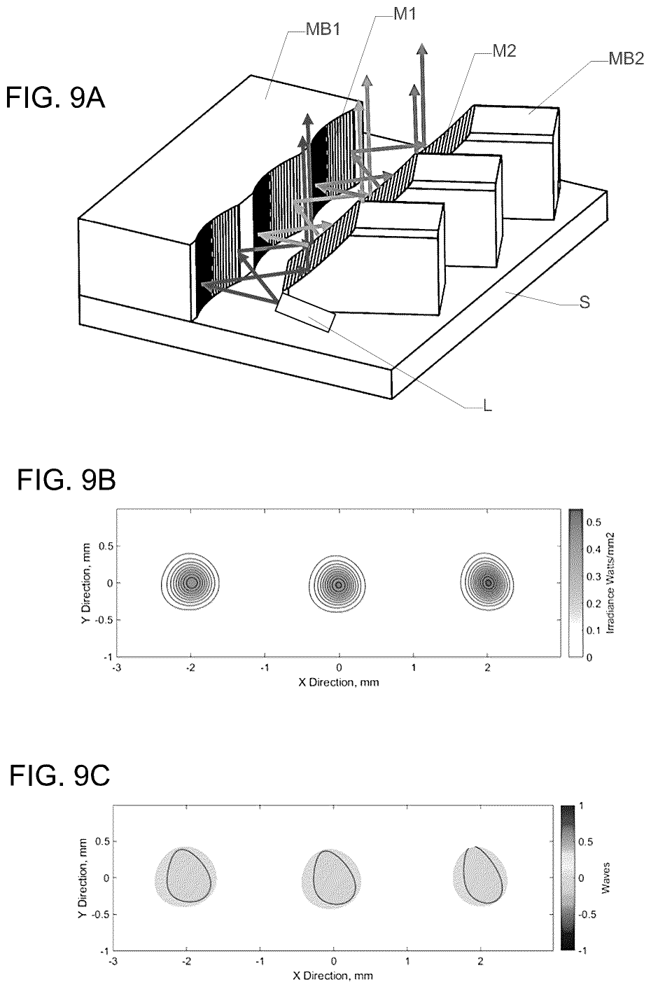

In a further embodiment of the present invention, an alternative approach that improves the circularity of the output beams is to collimate the slow axis and fast axis separately at different locations. FIG. 9A is a schematic perspective layout of two complementary mirror array blocks for turning and reshaping (collimation) of a plurality of laser beams, in accordance with one embodiment of the present invention. As illustrated in FIG. 9A, a mirror array includes two stamped mirror array blocks MB1 and MB2 in the form of metallic optical benches (MOB s) are deployed, each having a set of mirrors to achieve overall slow axis collimation, fast axis collimation, and beam folding/turning. As depicted in FIG. 9A, there are three lasers L, but only one is visible in the view in FIG. 9A. The other two lasers are each between the sub-blocks of the two mirrors M2. The mirror array configuration in FIG. 9A may be incorporated in a hermetically sealed LBM package (e.g., including frame, cover and substrate as were in the cases of the earlier discussed embodiments, e.g., FIG. 8A.)

In this embodiment, the fast axis of the laser beams from the lasers L is first collimated and reflected sideways by three freeform aspherical cylindrical mirrors M1 on the mirror array block MB1. The slow axis of the laser beams is then collimated and the laser beams are folded upward by the other set of freeform aspherical cylindrical mirrors M2 on the mirror array block M2. The beam profile and residual wavefront of the collimated beam are presented in FIGS. 9B and 9C, respectively. FIG. 9B schematically depicts optical simulation of beam profiles at a target plane at a reference distance (e.g., at 10 mm from the lasers L); FIG. 9C schematically depicts optical simulation of residual wavefronts for the collimated beams at the target plane at the reference distance.

In FIG. 9A, the second mirror array block MB2 is schematically shown to be three separate sub-blocks to avoid obscuring the reflective surfaces of mirrors M2. It is understood that two or more of the sub-blocks could be comprised in a single integral/monolithic block without departing from the scope and spirit of the present invention. Furthermore, in FIG. 9A, the first and second mirror array blocks MB1 and MB2 are schematically shown to be two separate sub-blocks to avoid obscuring an understanding of the structure. It is understood that the two mirror array blocks MB1 and MB2 could be comprised in a single integral/monolithic block without departing from the scope and spirit of the present invention.

In this embodiment, if the fast axis collimation mirrors M1 and slow axis collimation mirrors M2 are integrated into a single component (i.e., the mirror array blocks MB2 are integrated in a single monolithic component), optical alignment of the mirrors M1 and M2 can be achieved by precision stamping processes. In essence, for each laser beam, two aspherical mirrors are integrated into a single stamped optical bench to collimate and beam shape the light from the corresponding laser. No active alignment between slow and fast axis mirrors M1 and M2 would be necessary during assembly. This improves cost and reliability by eliminating adhesive joints and curing operations.

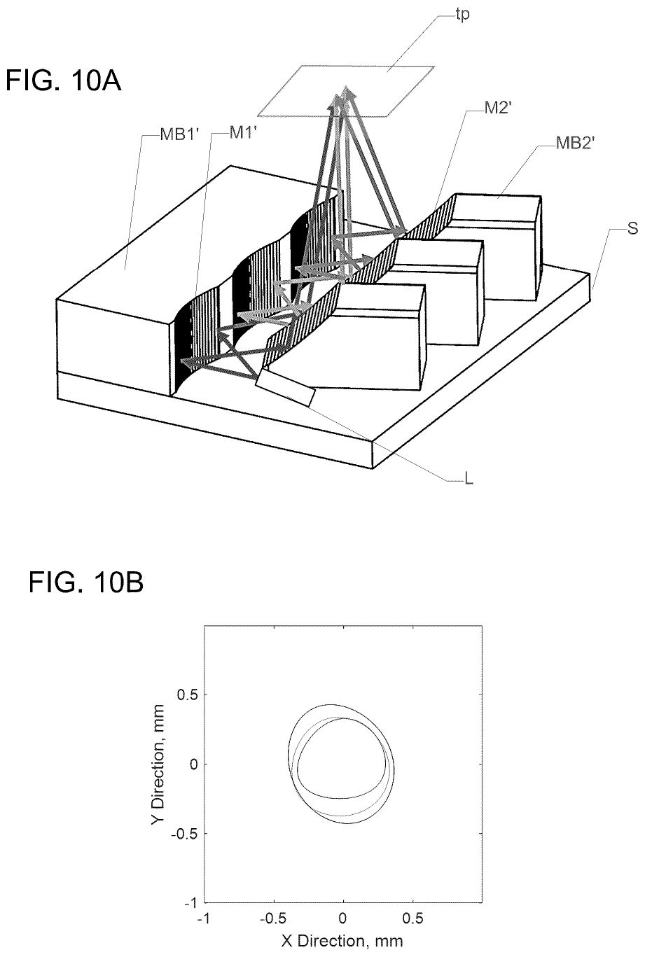

FIG. 10A is a schematic perspective layout of two complementary mirror array blocks for turning, reshaping, redirecting and combining of a plurality of laser beams at a target plane at a reference distance (e.g., a distance of 30 mm from the height of the laser L), in accordance with one embodiment of the present invention. As illustrated in FIG. 10A, a mirror array includes two stamped mirror array blocks MB1′ and MB2′ in the form of metallic optical benches (MOBs) are deployed, each having a set of mirrors to achieve overall slow axis collimation, fast axis collimation, and beam folding and redirecting to combine the beams at the target plane. FIG. 10B schematically depicts beam overlap for the laser beams at the target plane at the reference distance. As depicted in FIG. 10A, there are three lasers L, but only one is visible in the view in FIG. 10A. The other two lasers are each between the sub-blocks of the two mirrors M2′. The mirror array configuration in FIG. 10A may be incorporated in a hermetically sealed LBM package (e.g., including frame, cover and substrate, as were in the cases of the earlier discussed embodiments, e.g., FIG. 8A.)

In this embodiment, the fast axis of the laser beams from the lasers L is first collimated and reflected sideways by three freeform aspherical cylindrical mirrors M1′ on the mirror array block MB1′. For this set of mirrors M1′, they may have similar reflective profile as that of the set of mirrors M1 in the previous embodiment. The slow axis of the laser beams is then collimated, and the laser beams are folded upwards and redirected by the other set of freeform aspherical cylindrical mirrors M2′ on the mirror array block M2′. The beam profile of the collimated beams are presented in FIG. 10B, showing beam overlap at 1/e² intensity for the three beams at the reference target plane tp.

In FIG. 10A, the second mirror array block MB2′ is schematically shown to be three separate sub-blocks to avoid obscuring the reflective surfaces of mirrors M2′. It is understood that two or more of the sub-blocks could be comprised in a single integral/monolithic block without departing from the scope and spirit of the present invention. Furthermore, in FIG. 10A, the first and second mirror array blocks MB1′ and MB2′ are schematically shown to be two separate sub-blocks to avoid obscuring an understanding of the structure. It is understood that the two mirror array blocks MB1′ and MB2′ could be comprised in a single integral/monolithic block without departing from the scope and spirit of the present invention.

In this embodiment, if the fast axis collimation mirrors M1′ and slow axis collimation mirrors M2′ are integrated into a single component (i.e., the mirror array blocks MB2′ are integrated in a single monolithic component), optical alignment of the mirrors M1′ and M2′ can be achieved by precision stamping processes. In essence, for each laser beam, two aspherical mirrors are integrated into a single stamped optical bench to collimate and beam shape the light from the corresponding laser. No active alignment between slow and fast axis mirrors M1′ and M2′ would be necessary during assembly. This improves cost and reliability by eliminating adhesive joints and curing operations.

As can be further appreciated, further improvements in size, weight, reliability, and cost are achievable if the RGB beams are not combined using dichroic filter assembly. The inventive stamped mirror array essentially applies a rigid body rotation of the two sets of mirror surfaces to overlap the beams at a desired location (e.g., a scanning mirror for XR applications), thereby eliminating any need for a separate dichroic filter assembly.

While the invention has been described in reference to the illustrated embodiment of aspherical reflective surfaces as an example of freeform reflective surfaces, other freeform reflective optical surfaces can be adopted without departing from the scope and spirit of the present invention.

While the invention has been particularly shown and described with reference to the preferred embodiments, it will be understood by those skilled in the art that various changes in form and detail may be made without departing from the spirit, scope, and teaching of the invention. Accordingly, the disclosed invention is to be considered merely as illustrative and limited in scope only as specified in the appended claims.

We claim:

1. A laser beam module package, comprising:
an array of lasers outputting incident laser beams having an elliptical cross-sectional beam profile due to astigmatism of the incident laser beams;
a housing having a substrate supporting a frame having a top side, wherein the housing has a space bounded by the frame receiving the array of lasers and supporting the array of laser on the substrate within the space;
an optically transparent cover hermetically sealed to the top side of the frame; and
a mirror array comprising a mirror body of a metal material having a plurality of mirrors defined on a surface of the mirror body by metal stamping the surface of the mirror body to form an array of smooth freeform reflective surfaces of the array of mirrors, wherein the mirror body is supported by, and received within the space of, the housing, wherein the array of mirrors are optically aligned to the array of lasers, wherein the freeform reflective surfaces are configured to reflect and reshape the beam profile of the corresponding incident laser beams to produce corresponding output laser beams that are directed towards the cover to be output from the laser beam module package.
